(19) United States
(12) Patent Application Publication
(10) Pub. No.: US 2020/0216222 A1
(43) Pub. Date: Jul. 9, 2020

(54) DEVICE FOR COATING CONTAINERS

(71) Applicant: KHS CORPOPLAST GMBH, Hamburg (DE)

(72) Inventors: Joachim KONRAD, Duesseldorf (DE); Sebastian KYTZIA, Todesfelde (DE); Michael HERBORT, Hamburg (DE)

(21) Appl. No.: 16/643,796

(22) PCT Filed: Sep. 7, 2018
(86) PCT No.: PCT/EP2018/074079

§ 371 Date: Mar. 2, 2020

(30) Foreign Application Priority Data
Sep. 7, 2017 (DE) 10 2017 120 649.3

(51) Int. Cl. B65D 23/02; C23C 16/04

(52) U.S. Cl. CPC B65D 23/02; B65D 23/0807; C23C 16/045

(57) ABSTRACT

Device for coating containers by a coating method. The device includes a carrier frame having outer dimensions less than the inner dimensions of an ISO container. The carrier frame includes within its outer dimensions: a conveying region where a conveying device for the containers is arranged; a treatment region where a container treatment unit for coating the containers is arranged; a transfer region where a transfer device is arranged; which moves the containers between the conveying device and the container treatment unit; a maintenance region accessible from outside, in which no components are arranged; an electronics region, where a switchgear cabinet for the electronics of the components of the device is arranged; a process-gas processing region, where the components for handling the process gas for the coating method are arranged; and a vacuum pump region, where vacuum pumps for producing the vacuum needed for a coating method are arranged.

### FIELD OF INVENTION

The present invention relates to a device for coating containers by means of a coating method.

### BACKGROUND OF INVENTION

Container coating machines known from the prior art are used, among other purposes, for coating the inner surfaces of containers, such as PET bottles. With such systems, the containers are conveyed into a conveying region, from there by means of a transfer device, such as a gripper, to a device and transferred to this, by means of which a process gas is introduced into the container and its inner surface is therefore coated. After the coating has been carried out, the transfer device brings the container back into the conveying region. From there it is conveyed out and passes into the further production chain. Such systems must be brought to the intended location in prefabricated individual parts, which include, for example, a conveying device, the transfer device, a treatment unit, a vacuum system, and a device for the process gas of the coating process, usually in each case with a separate electronics system, and installed there with considerable effort and expense.

In this situation, the coating method is in particular a deposition method, which takes place under a vacuum, and preferably a CVD (Chemical Vapor Deposition) method.

### SUMMARY OF INVENTION

The object of the present invention is to provide a total device which can more easily installed at its location, and which is easy to transport.

This object is solved according to the invention by a device with the features of claim 1. According to this, provision is made that all operations of a device for the coating of containers by means of a coating method, in particular a CVD method, are arranged in one carrier frame. This carrier frame can either be of one piece or multi-part. Due to the fact that the carrier frame has outer dimensions which are smaller than the inner dimensions of an ISO container, which is also designated as an overseas container and is standardised in accordance with ISO Standard 668, which cites it as having outer dimensions with a length of 20 feet (6.096 m) or 40 feet (12.192 m), the 40 feet version also being known according to the standard in a higher version (40′ HC), it having an outer height of 2.896 m instead of 2.591 m, and none of its components projecting over its outer dimensions, the device can be almost entirely pre-installed at the manufacturers' premises and then transported in such an ISO container, as a whole entity, to the intended location safely and easily. The device according to the invention comprises all the regions required for operation: Conveying region, transfer region, treatment region, electronics region, process-gas processing region, and vacuum pump region. Either the regions referred to are already equipped with the necessary components before transport, or these can simply be installed into the device, on the basis of the separated regions, at the planned location. In addition to this, a maintenance region is also present in the device according to the invention, in which no components are arranged. From there, maintenance can be carried out of regions of the device which are otherwise difficult to access more easily than with conventional devices for the coating of containers by means of a coating method.

An advantageous further embodiment of the invention makes provision for the carrier frame to be configured in such a way that the components are enclosed in the individual regions in the form of cages or grids, at least on four sides and preferably on all six sides. As a result, good protection of the components of the device, which in part are highly sensitive, is ensured by the solid and stable carrier frame.

An advantageous further embodiment of the invention makes provision for the sequence of the regions in the longitudinal direction to be as follows: Conveying region, transfer region, treatment region, maintenance region, and then a process segment arranged connecting to this, which comprises, in any desired order in relation to one another, the electronics region, the process-gas processing region, and the vacuum pump region. In particular, by the arrangement of the maintenance region on the rear side and directly in connection with the treatment region with the container treatment unit, it can be easily reached in the event of problems, unlike the situation with devices regularly known from the prior art, and the repair or maintenance work can be carried out with no problem.

A further advantageous embodiment of the invention makes provision for further regions to be connected to the process segment in the longitudinal direction, in the following sequence: A further maintenance region, a further treatment region, a further transfer region, and a further conveying region, wherein the components in the process segment serve the regions which are already present as well as those which are added. As a result, an essentially mirror-image arrangement of the device around the process segment is obtained, with two container treatment units and respective delivery devices, wherein the components of the process segment are only simply present and are used in common by the duplicated components. As a result, the doubled quantity of containers can be coated per time unit, as a result of which the costs for this are perceptibly lower than if two devices were to be procured; as well as that, space is also saved, since the components of the process segment do not have to be present in a duplicated arrangement.

A further advantageous embodiment of the invention makes provision for further regions to be connected between the maintenance region and the process segment: A further treatment region, a further transfer region, and a further conveying region. As a result of this, too, a doubled throughput of containers is attained. The only difference in relation to the configuration according to the preceding paragraph lies in the fact that a mirror-image arrangement of the components coming in direct contact with the containers is present around a common maintenance region, and the process segment connects to this. The advantages correspond to the advantages described in the preceding paragraph.

A further advantageous embodiment of the invention makes provision for the transfer device in the transfer region and/or further transfer regions to comprise in each case at least one gripper carriage, and the treatment unit in the treatment region and/or further treatment regions to comprise in each case a predetermined number of places, preferably four places, which are configured as individual vacuum chambers or common vacuum chambers. By means of a gripper carriage, a good movement of the containers from the conveying device to the container treatment unit is achieved, and the transfer is carried out very precisely in both directions. Due to the plurality of places of the container treatment unit, an increase in the throughput can be achieved in comparison with the use of only one single place; the gripper carriage can also be equipped with the same number of grippers as there are places at the container treatment unit.

A further advantageous embodiment of the invention makes provision for a first gripper carriage to be arranged between a first conveying region and a first treatment region, and a second gripper carriage to be arranged between a second conveying region and a second treatment region, wherein the first conveying region is arranged along a face surface of the carrier frame and the second conveying region is arranged between the treatment regions and the process segment, wherein a further maintenance region for the second treatment region is arranged at the same face surface of the carrier frame as the first conveying region, and the maintenance region for the first treatment region, like the second conveying region, is arranged between the treatment regions and the process segment. This represents a further possibility for a compact device, and at the same time with efficient use of the components of the process segment, as was already the case heretofore for the two other configurations with two treatment regions in each case. With regard to the advantages, reference is made to the descriptions provided there.

A further advantageous embodiment of the invention makes provision for at least one of the conveying devices to comprise an automated adjustment device for the width of its channels. This makes it possible for containers of different sizes, in particular of bottles of different diameters, to be conveyed and transferred securely and reliably with the same device, without any heightened risk of falling over, as would be the case with a channel much wider than the diameter of the container being treated at that particular time.

A further advantageous embodiment of the invention makes provision for the conveying region and/or the further conveying region to comprise in each case two part conveying devices, detached from one another, a delivery conveying device, and an output conveying device. As a result, containers can already be delivered and handed over for transfer while containers are still being placed on the other part conveying device, and this is therefore not yet moving. The same also applies in reverse: The part conveying device for delivery is already standing still, since the containers located there are being taken over by the transfer device, while the other part conveying device is outputting containers.

A further advantageous embodiment of the invention makes provision for the process-gas processing region to comprise an unheated region, in which a carrier gas mass flow regulator and an absolute pressure detector are arranged. Accordingly, these devices can be operated within their specifications. This would not be the case if these devices, as is regularly the case in the prior art, together with the mass flow regulators of the monomers in a heated region of the process-gas system; the higher temperature with these latter volume flow regulators is necessary in order to attain higher volume flows of the process gas.

A further advantageous embodiment of the invention makes provision for the vacuum pump region to comprise two part regions, ideally two spatially separated part regions: A pre-vacuum part region for producing a pre-vacuum and a process-vacuum part region for producing a process vacuum. As a result, the components required for producing the pre-vacuum can be easily replaced together; the same applies to the components which belong together for producing the process vacuum.

All the features of the advantageous embodiments referred to in the sub-claims form part of the invention, both individually as well as in any desired combination.

### BRIEF DESCRIPTION OF DRAWINGS

Further details and advantages of the invention are explained in greater detail on the basis of exemplary embodiments represented in the drawings.

The figures show:

FIG. 1 An oblique view of a carrier frame according to the invention of a device according to the invention,

FIG. 2 a schematic representation of a first exemplary embodiment of a device according to the invention in a view from above,

FIG. 3 a schematic representation of a second exemplary embodiment of a device according to the invention in a view from above,

FIG. 4 a schematic representation of a third exemplary embodiment of a device according to the invention in a view from above,

FIG. 5 a schematic representation of a fourth exemplary embodiment of a device according to the invention in a view from above,

FIG. 6 a schematic representation of a fifth exemplary embodiment of a device according to the invention in a view from above, and

FIG. 7 a schematic representation of a sixth exemplary embodiment of a device according to the invention in a view from above.

### DETAILED DESCRIPTION OF INVENTION

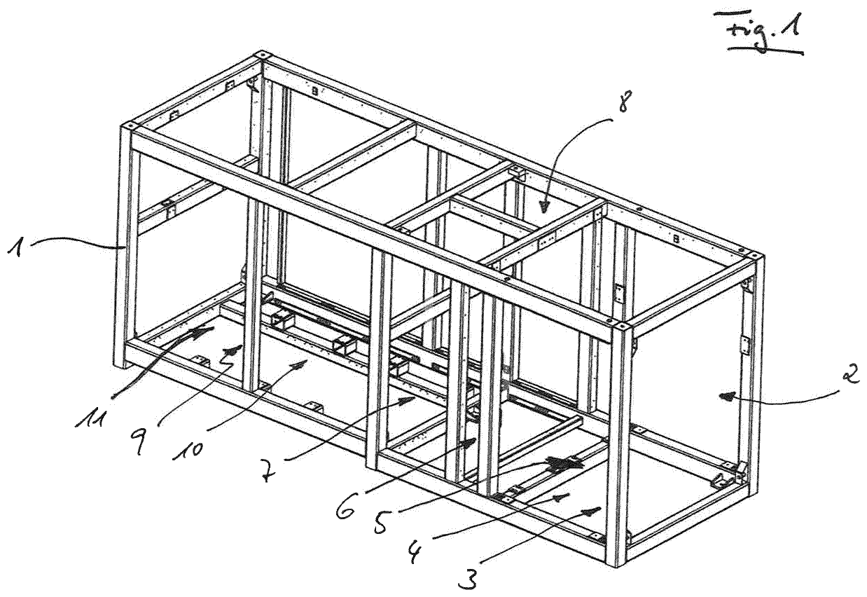

FIG. 1 shows a carrier frame 1 according to the invention of a device according to the invention for the coating of containers by means of a coating method. The carrier frame 1 exhibits a cage-like structure. The components necessary for the coating are inserted into it, such that they do not project over its outer members. As a result, these components (not represented) are also well protected by the carrier frame 1 during the transport of the device. The outer members of the carrier frame essentially span a rectangular parallelepiped or cuboid. The outer dimensions of this parallelepiped are such that it fits into an ISO container. The internal dimensions of such an ISO container (the dimensions given are those of a 40 feet HC model (40′ HC)) are: Width 2.352 m; height 2.698 m; length 12.032 m. A 20 feet model (20′) differs from this only in its length, which amounts to 5.898 m. A 40 feet model (40′) differs from the first named version only in its height, which amounts to 2.385 m.

The outer dimensions of the carrier frame 1 are selected in such a way that they are slightly smaller in width and height than the inner dimensions indicated above of the ISO container. For example, the exemplary embodiment represented in FIG. 1 exhibits a width of 2.150 m, a height of 2.560 m, and a length of 6.292 m. Since the components located in the carrier frame 1 do not project beyond these, the device for coating containers by means of a coating method, with all the components required, can be loaded as a whole into an ISO container, and transported with this easily and securely to the place of installation. There the device is then taken out the ISO container and can be integrated into a production chain with only little effort, in that interfaces for this are connected to a conveying device (or several conveying devices) inside the carrier frame 1.

Formed in the carrier frame are different regions, which are either delimited from one another by corresponding frame members or of which several are grouped together by corresponding frame members. Starting from its face side 2, the sequence of these regions is as follows:

A conveying region 3; connected to this, a transfer region 4, and connected to this a treatment region 5. These three regions extend over the entire width of the carrier frame 1. They are formed between the first and second vertical members of the carrier frame 1.

Between the second and third vertical member is a maintenance region 6, which likewise extends over the entire width of the carrier frame 1.

Arranged next to one another, between the third and fourth vertical members, are two regions: In the representation, seen from the face side 2, on the left is an electronics region 7 and on the right a process-gas processing region 8.

Formed between the fourth and sixth (last) members is a vacuum pump region 9, in which the components are located which are necessary for producing the vacuum required for the coating process. The vacuum pump region 9 in this situation is divided by the fifth vertical member into two part regions. Seen from the face side 2 of the carrier frame 1, in front of this frame member is a part region, designated within the framework of this Application as the pre-vacuum part region 10, which serves to produce the pre-vacuum; behind the fifth vertical member is a part region, designated within the framework of this Application as the process vacuum part region 11, which serves to produce the process vacuum.

The member grid, i.e. the position and number of the vertical members, can of course be varied as may be required.

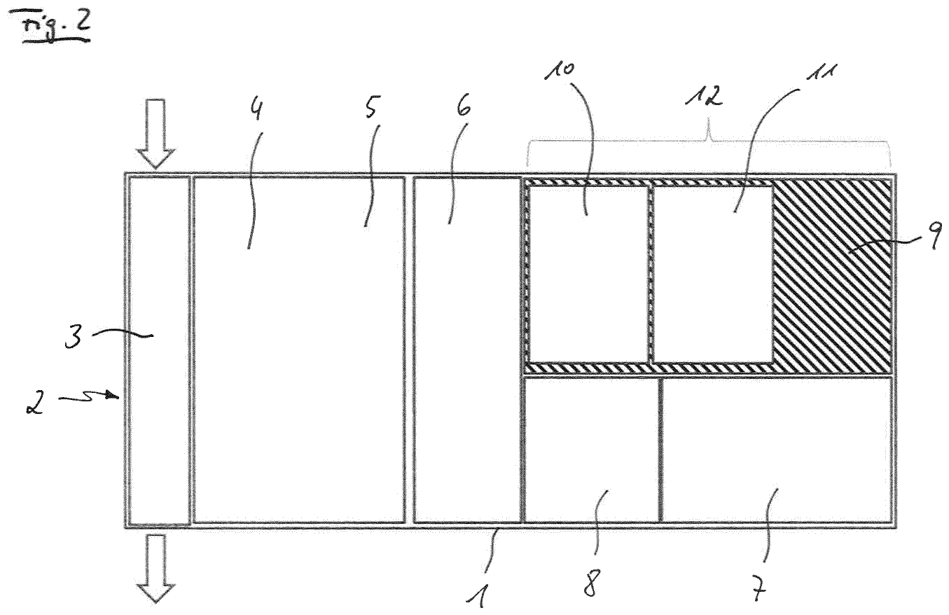

Represented in FIGS. 2 to 7 are six exemplary embodiments according to the invention, which have different arrangements of the regions. These Figures show in each case schematically greatly simplified views from above.

In FIG. 2, at the face side 2 of the carrier frame 1 is the conveying region 3, in which one single continuous conveying device is provided in the form of a conveyor belt. The delivery conveying direction (upwards in FIG. 2) and the output conveying direction (downwards in FIG. 2) is indicated by the arrows. Provided at the respective intersection points (see arrows) to the device according to the invention are interfaces for coupling the device into a production line.

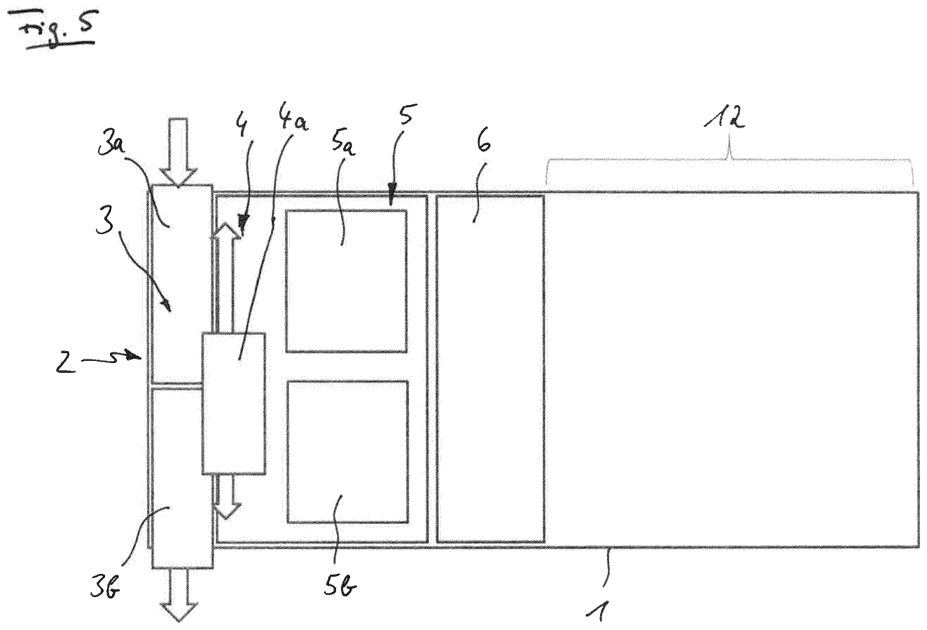

Arranged in the transfer region 4 is a transfer device, such as, for example, a gripper carriage 4a, 4b, 4c (see FIGS. 5-7), which grips the containers being conveyed inwards on the conveyor belt, and moves them into a treatment unit 5a, 5b provided in the treatment region 5 see FIGS. 5-7). There the containers are coated by means of a coating method. After the coating process has been carried out, the containers are moved by the transfer device back again to the conveyor belt and there placed on it such that output conveying takes place in the direction of the lower arrow and the coated containers run in the production chain again.

The maintenance region 6 formed behind the treatment region 5 is easily accessible from the outside (for example by way of a door). There are no components arranged in it, and it is easy to access the treatment unit in order to be able to maintain or repair it.

In order to carry out the coating method and process, appropriate process gases are needed, which in part need to be processed. These are then conveyed via pipes (not represented) from the process-gas processing region 8 to the treatment unit. Advantageously, in the process-gas processing region 8 is a region which in particular is not heated, arranged in which are all the technical method and process components required for this purpose, such as a carrier gas mass flow regulator and an absolute pressure detector. These devices can accordingly be operated within their specifications. This would be perceptibly more difficult, or not the case at all, if these devices were arranged together with the mass flow regulators of the monomers in another heated part region of the process-gas processing region 8; the higher temperature with the mass flow regulators last referred to is necessary in the region of the process-gas system, in order to attain higher volume flows of the process gas.

Since the process-gas processing region 8 does not extend over the entire width of the carrier frame 1, it is arranged in the other part of the vacuum pump region 9. In this the vacuum is produced which is likewise needed for the coating method. A number of vacuum pumps are required for this. These are arranged in separate part regions, depending on their function; there are vacuum pumps which are required for producing a pre-vacuum, these being grouped together in the pre-vacuum part region 10, and there are vacuum pumps which are necessary for producing a process vacuum, these being grouped together in the process vacuum part region 11. The vacuum pumps are connected to one another and to the treatment unit by way of pipes, not shown. Due to the modular grouping, the components which belong together can be replaced more easily.

In order to provide electric current to all the components arranged inside the carrier frame 1, to control their function, etc., all the corresponding electrical and electronic components are grouped together in a switchgear cabinet. For this purpose, all such components are arranged readily accessible in immediate proximity to one another, which is maintenance-friendly and repair-friendly.

The last-named regions, the electronics region 7, the process-gas processing region 8, and the vacuum pump region 9, grouped together, are also designated as the process segment.

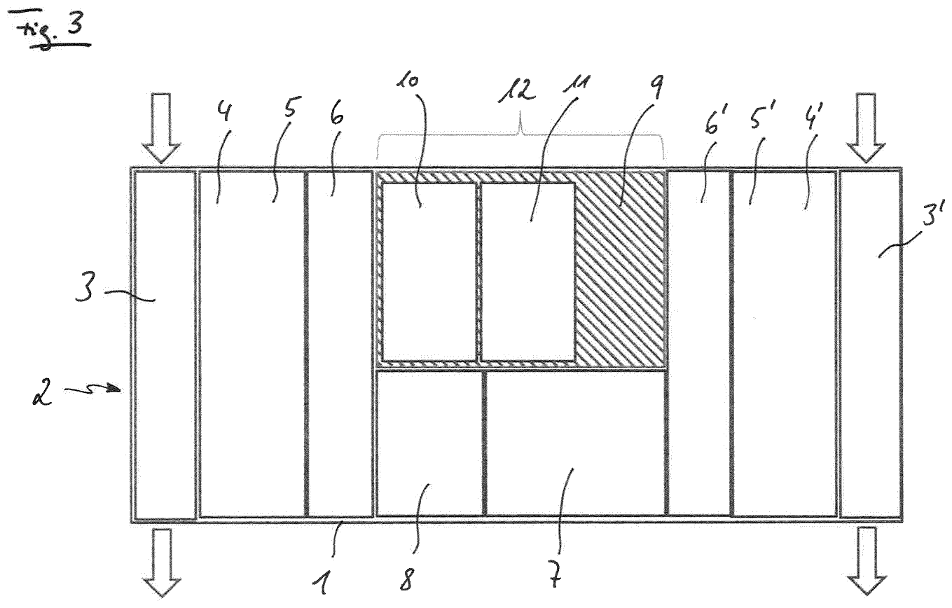

The exemplary embodiment represented in FIG. 3 differs from that in FIG. 2 only in that, seen from the face side 2, behind the process segment 12, essentially mirror-image to the regions of the first conveying region 3, the first transfer region 4, the first treatment region 5, and first maintenance region 6, these regions are then again present in the reverse order. Starting from the process segment, these are a second maintenance region 6′, a second treatment region 5′, a second transfer region 4′, and a second conveying region 3′. Their functions are the same as the corresponding regions which were described in FIG. 2. The advantage in this situation is that double the throughput can be achieved with a device according to FIG. 2, but the components of the process segment do not have to be doubled as well, which saves space and costs.

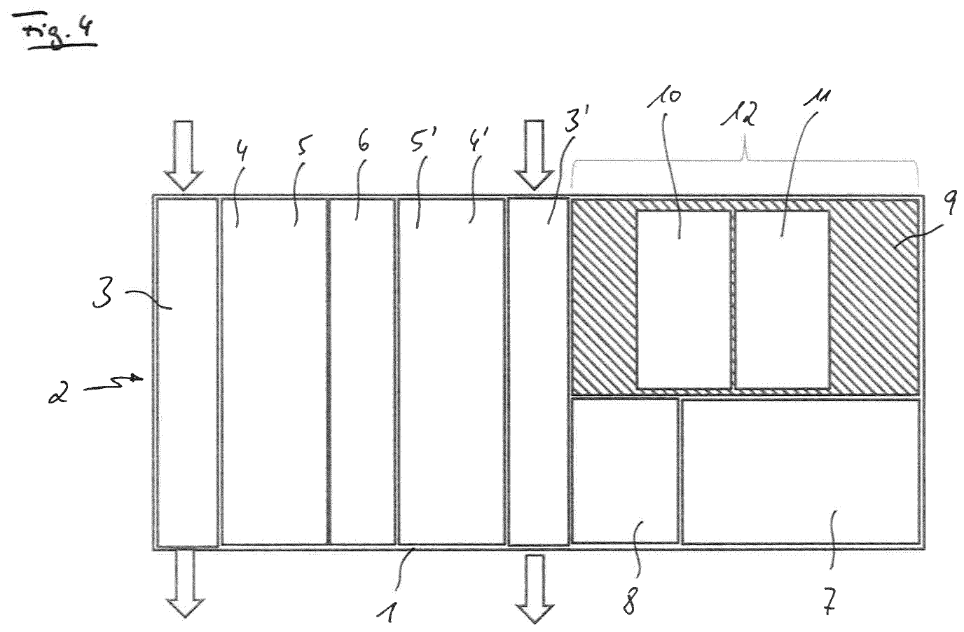

The difference between the exemplary embodiment from FIG. 4 and that of FIG. 3 consists only of the fact that the second regions, which in FIG. 2 were arranged to the right of the process segment 12, are now arranged between the process segment 12 and the (first) maintenance region 6, and this (first) maintenance region 6 coincides with the second maintenance region 6′ from FIG. 3. Here too, the same throughput can be achieved as with the device according to FIG. 3.

The difference between the fourth exemplary embodiment from FIG. 5 and the first exemplary embodiment from FIG. 2 lies in the fact that there is not a continuous conveyor belt present in the conveying region 3, but two conveyor belts which can be operated separately from one another: A delivery conveying device 3a and an output conveying device 3b. This allows for the delivery conveying to take place independently of the output conveying. This has the advantage, for example, with the use of a (single) gripper carriage 4a, that while this raises the containers from the stopped delivery conveying device 3a, containers standing on the output conveying device 3b can be conveyed out of the system. This of course also applies to the reverse situation. The individual gripper carriage 4a services two treatment units, in particular with several stations in each case, a first treatment unit 5a and a second treatment unit 5b. This allows for a higher throughput to be achieved than if only one treatment unit were present.

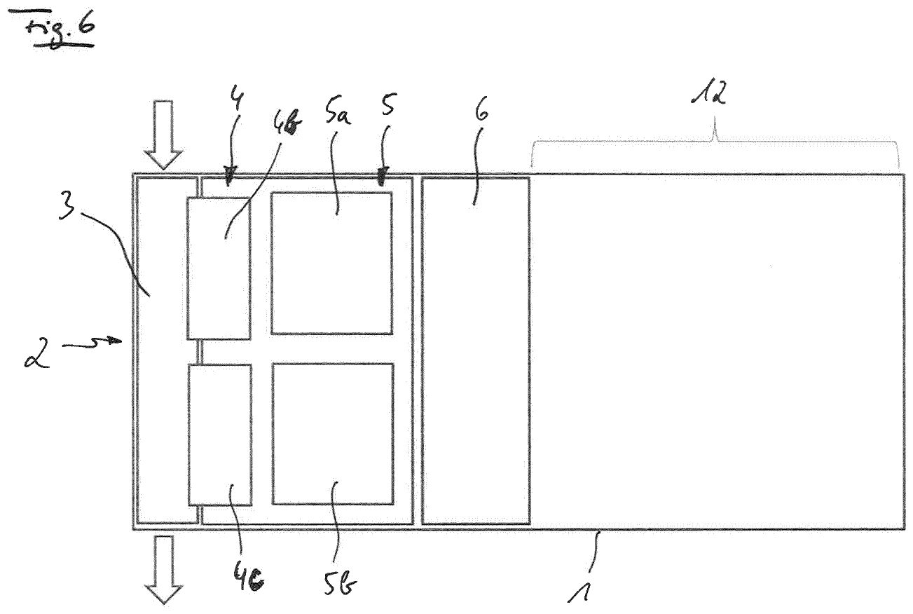

The difference between the fifth exemplary embodiment from FIG. 6 and the fourth exemplary embodiment from FIG. 5 lies in the fact that in the conveying region 3 only one single continuous conveying belt is present (as in the exemplary embodiments from FIGS. 2-4) and two gripper carriages, a first gripper carriage 4b, which is allocated to the first container treatment unit 5a, and a second gripper carriage 4c, which is allocated to the second container treatment unit 5b. As a result, while it is true that a faster loading of the two container treatment units 5a, 5b can be achieved, since one single gripper carriage does not need to travel constantly backwards and forwards (also in order to lift the containers from the delivery conveying device 3a over to the output conveying device 3b), nevertheless double the effort and expenditure is required with regard to the gripper carriages 4b, 4c.

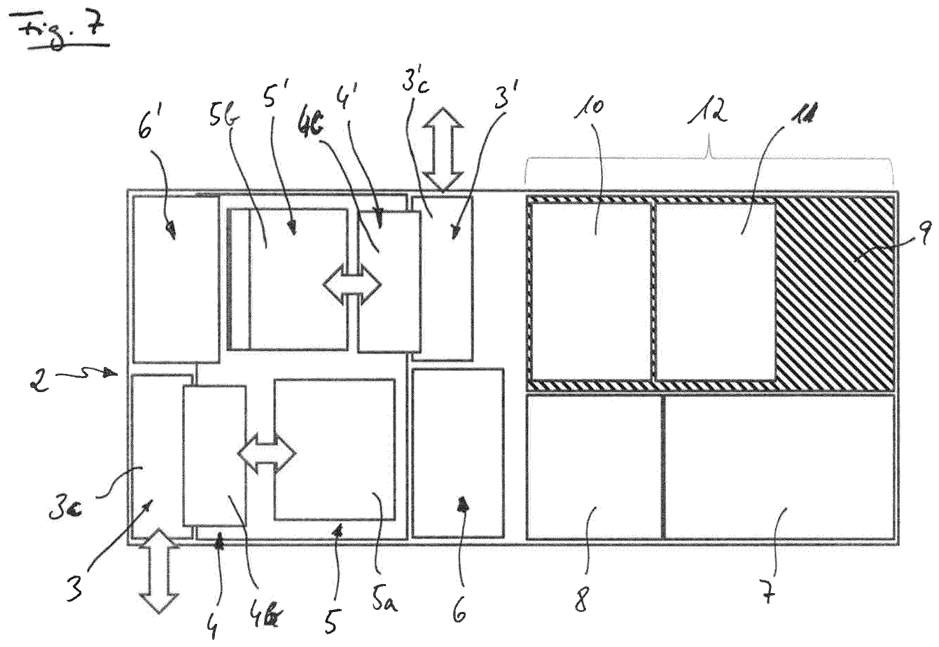

The sixth exemplary embodiment from FIG. 7 is changed in comparison with the third exemplary embodiment from FIG. 4 as follows: Instead of extending in each case over the entire width of the carrier frame 1, the assemblage of first conveying region 3, first transfer region 4, first treatment region 4, and first maintenance region 6 extend only over half its width. Arranged in the other half is a same assemblage, in the reverse order (starting from the face surface 2): Further maintenance region 6′, further treatment region 5′, further transfer region 4′, and further conveying region 3′.

The difference in relation to all the other exemplary embodiments lies in the fact that each of the two conveying devices arranged in the conveying regions 3, 3′, the first conveying device 3c and the second conveying device 3′c, must be capable of being driven in both directions, in order to be able to carry out both the delivery conveying of the uncoated containers as well as the output containing of the coated containers. This represents a further possibility for a compact device with, at the same time, efficient use of the components of the process segment 12, as was already the case heretofore with the two other embodiments with two treatment regions 5a, 5b in each case. With regard to the advantages, reference is made to the descriptions provided there. In a comparable manner to the fifth exemplary embodiment from FIG. 6, two gripper carriages are present, a first gripper carriage 4b, which is allocated to the first container treatment unit 5a, and a second gripper carriage 4c, which is allocated to the second container treatment unit 5b. It is true that the arrangement of the individual regions is not in the same direction in relation to FIG. 6, but in the opposite direction, but the same advantages are derived as described heretofore in respect of FIG. 6.

It is of course possible for alternative delivery conveyors and output conveyors to be provided for, such as, for example, parallel belts, wherein the associated grippers and a gripper carriage would have to be adapted accordingly.

### REFERENCE NUMBER LIST

1 Carrier frame
2 Face surface
3 (First) conveying region
3a Delivery conveying device
3b Output conveying device
3c First conveying device
3′ Further conveying device
3′c Second conveying device
(First) transfer region
4a Individual gripper carriage
4b First gripper carriage
4c Second gripper carriage
4′ Further transfer region
5 (First) treatment region
5a First container treatment unit
5b Second container treatment unit
5′ Further treatment region
6 (First) maintenance region
6′ Further maintenance region
7 Electronics region
8 Process-gas processing region
9 Vacuum pump region
10 Pre-vacuum part region
11 Process vacuum part region
12 Process segment

1. A device for coating containers by means of a coating method, with a carrier frame, of which the outer dimensions are smaller than the inner dimensions of an ISO container, wherein the following regions are present within the carrier frame:
a conveying region, arranged in which is at least one conveying device for the containers,
a treatment region is provided, arranged in which is at least one container treatment unit for coating the containers,
a transfer region, arranged in which is a transfer device, which moves the containers between the conveying device and the container treatment unit,
a maintenance region, easily accessible from the outside, which is arranged on the rear side of the at least one container treatment unit,
an electronics region, arranged in which is a switchgear cabinet for the electronics of the components of the device,
a process-gas processing region, arranged in which are the components for the handling of the process gas for the coating method and process,
a vacuum pump region, arranged in which are vacuum pumps for producing the vacuum required for the coating method and process.

2. The device according to claim 1, wherein the carrier frame is configured in such a way that it encloses the components in the individual regions on at least four sides, and preferably on all six sides, in the form of a cage or grid.

3. The device according to claim 1, wherein the sequence of the regions in the longitudinal direction is as follows: Conveying region, transfer region, treatment region, maintenance region; and connecting to them a process segment is arranged, which encloses in any desired arrangement to one another the electronics region, the process-gas processing region, and the vacuum pump region.

4. The device according to claim 3, wherein connected to the process segment in the longitudinal direction are further regions, in the following sequence: A further maintenance region, a further treatment region, a further transfer region, and a further conveying region, wherein the components in the process segment supply both the regions already present as well as the regions which are added.

5. The device-Device according to claim 3, wherein further regions are connected between the maintenance region (6) and process segment (12) in the following sequence: A further treatment region (5′), a further transfer region (4′), and a further conveying region (3′).

6. The device according to claim 1, wherein the components arranged in the said regions do not project over the region determined by the outer dimensions of the carrier frame.

7. The device according to claim 1, wherein the maintenance region, easily accessible from the outside, is arranged on the rear side of the treatment unit and no components are arranged therein

8. The device according to claim 1, wherein the transfer device in the transfer region and/or further transfer region comprises in each case at least one gripper carriage, and the treatment unit in the treatment region and/or further treatment region comprises in each case a vacuum chamber with a predetermined number of places, preferably four places.

9. The device according to claim 8, wherein a first gripper carriage is arranged between a first conveying region and a first treatment region and a second gripper carriage is arranged between a further conveying region and a further treatment region, wherein the first conveying region is arranged along a face surface of the carrier frame and the further conveying region is arranged between the treatment regions and the process segment, wherein a further maintenance region for the further treatment region (5′) is arranged at the same face surface of the carrier frame as the first conveying region, and the maintenance region for the first treatment region, like the second conveying region, is arranged between the treatment regions and the process segment.

10. The device according to claim 1, wherein at least one of the conveying devices comprises an adjustment device for the width of its channels.

11. The device according to claim 1, wherein the conveying region and/or the further conveying region in each case comprise two part conveying devices uncoupled from one another, a delivery conveying device (3b), and an output conveying device.

12. The device according to claim 1, wherein the process-gas processing region comprises an unheated region, arranged in which are a carrier gas mass flow regulator and an absolute pressure detector.

13. The device according to claim 1, wherein the vacuum pump region comprises two spatially separated part regions: A pre-vacuum part region for producing a pre-vacuum and a process vacuum part region for producing a process vacuum.
